(19) United States
(12) Patent Application Publication
(10) Pub. No.: US 2025/0060110 A1
(43) Pub. Date: Feb. 20, 2025

(54) SPLIT-TYPE RANGE HOOD HAVING RELAY FAN FOR COOLING CIRCUIT BOARD

(71) Applicant: BLUESKY COOKING STYLE CO., LTD., Taipei City (TW)

(72) Inventor: CHIN-JUNG LIAO, Taipei City (TW)

(21) Appl. No.: 18/780,531

(22) Filed: Jul. 23, 2024

(30) Foreign Application Priority Data
Aug. 18, 2023 (TW) 112131092

(51) Int. Cl. F24C 15/20; H05K 7/20

(52) U.S. Cl. CPC F24C 15/2021; H05K 7/2039

(57) ABSTRACT

A split-type range hood includes a range hood body, an air duct, and a relay fan. The range hood body includes a chassis and a smoke collecting box that has an exhaust opening. The relay fan is disposed outside of the range hood body, and includes a suction motor, a heat-dissipation base, and a circuit board. The suction motor includes a motor body and an outer housing having first and second openings that are opposite to each other. Two ends of the air duct are in air communication with the exhaust opening and the first opening, respectively. The heat-dissipation base is disposed on the outer housing. The circuit board is electrically connected to the suction motor, and is disposed on the heat-dissipation base, so that the circuit board is cooled by cooling the heat-dissipation base with a suction airflow of the suction motor during operation.

### CROSS-REFERENCE TO RELATED PATENT APPLICATION

This application claims the benefit of priority to Taiwan Patent Application No. 112131092, filed on Aug. 18, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a range hood, and more particularly to a split-type range hood having a relay fan for cooling a circuit board.

### BACKGROUND OF THE DISCLOSURE

For a split-type range hood, a range hood body and a motor (otherwise referred to as a relay motor or a relay fan) are designed to be separate from each other, so that the relay fan can be arranged outside of a kitchen. In this way, motor noise generated during cooking can be reduced. An air duct is required for connecting the range hoody body and the relay fan, so as to discharge airborne grease to the outside. Furthermore, in order to control the relay fan and provide electricity, the range hoody body is usually provided with a control box. One end of the control box is connected to utility power, and another end of the control box is connected to the relay fan via an extension cord, so that the relay fan can be controlled, and the electricity can be provided. However, heat generated by a high-power electronic component disposed on a circuit board of the control box increases with an increase of power consumption of the relay fan. Conventionally, a heat-dissipation device is disposed in the control box, so as to dissipate the high heat generated by the high-power electronic component. While placing a heat-dissipation fan is one convenient way to improve the heat-dissipation ability of the heat-dissipation device, additional electricity is needed for the heat-dissipation fan. Moreover, the heat-dissipation fan is likely to malfunction in a high-temperature environment and requires frequent repair, which has long been an issue that troubles manufacturers and users.

### SUMMARY OF THE DISCLOSURE

In response to the above-referenced technical inadequacies, the present disclosure provides a split-type range hood having a relay fan for cooling a circuit board.

In order to solve the above-mentioned problems, one of the technical aspects adopted by the present disclosure is to provide a split-type range hood, which includes a range hood body, an air duct, and a relay fan. The range hood body includes a chassis and a smoke collecting box, the chassis has an intake opening, the smoke collecting box is disposed on the chassis, the smoke collecting box covers the intake opening, the smoke collecting box has an exhaust opening, and the exhaust opening of the smoke collecting box is in air communication with the intake opening of the chassis. The relay fan is disposed outside of the range hood body, and includes a suction motor, a heat-dissipation base, and a circuit board. The suction motor includes an outer housing and a motor body, and the outer housing has a first opening and a second opening that are opposite to each other. One end of the air duct is in air communication with the exhaust opening, and another end of the air duct is in air communication with the first opening. The motor body is disposed in the outer housing, and an outlet that corresponds in position to the second opening is formed at one end of the motor body. The heat-dissipation base is disposed on the outer housing of the suction motor. The circuit board is electrically connected to the motor body of the suction motor, and is disposed on the heat-dissipation base, so that the circuit board is cooled by cooling the heat-dissipation base with a suction airflow of the suction motor during operation.

In one of the possible or preferred embodiments, the range hood body further includes a smoke deflector, an inclined angle of the smoke deflector is adjustable, and the smoke deflector is rotatably connected to one side of a bottom portion of the chassis.

In one of the possible or preferred embodiments, a third opening that corresponds in position to the heat-dissipation base is formed on the outer housing of the suction motor, and the heat-dissipation base sinks into the outer housing through the third opening.

In one of the possible or preferred embodiments, the relay fan further includes an outer cover shell, the outer cover shell covers an outer periphery of the circuit board, and one or more drain holes are formed on the outer cover shell.

In one of the possible or preferred embodiments, the heat-dissipation base is a metal heat-dissipation base that has a hollow rectangular column shape, the heat-dissipation base partially sinks into the outer housing, the heat-dissipation base has a heat-dissipation wall and two side openings, and the two side openings are respectively formed on two sides of the heat-dissipation wall. A plurality of heat-dissipation holes are formed on the heat-dissipation wall, and are in air communication with the two side openings. The two side openings are in air communication with an inner space of the outer cover shell and the one or more drain holes.

In one of the possible or preferred embodiments, the outer cover shell includes two side cover plates that are opposite to each other, and one of the drain holes is formed on each of the two side cover plates.

In one of the possible or preferred embodiments, the one end of the air duct is connected to the exhaust opening of the smoke collecting box via a first sleeve, and the another end of the air duct is connected to the first opening of the outer housing via a second sleeve.

In one of the possible or preferred embodiments, the relay fan further includes a relay transceiver. The relay transceiver is electrically connected to the circuit board, and is configured to amplify and broadcast a relay fan activation signal transmitted by the range hood body during activation.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic exploded perspective view of a split-type range hood according to the present disclosure;

FIG. 2 is another schematic exploded perspective view of the split-type range hood according to the present disclosure;

FIG. 3 is a schematic exploded perspective view of a relay fan according to the present disclosure;

FIG. 4 is a schematic perspective view of the relay fan that is partially assembled according to the present disclosure;

FIG. 5 is a schematic perspective view of the relay fan that is assembled according to the present disclosure;

FIG. 6 is a schematic cross-sectional view of the relay fan according to the present disclosure; and

FIG. 7 is a schematic diagram showing a use status according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Embodiment

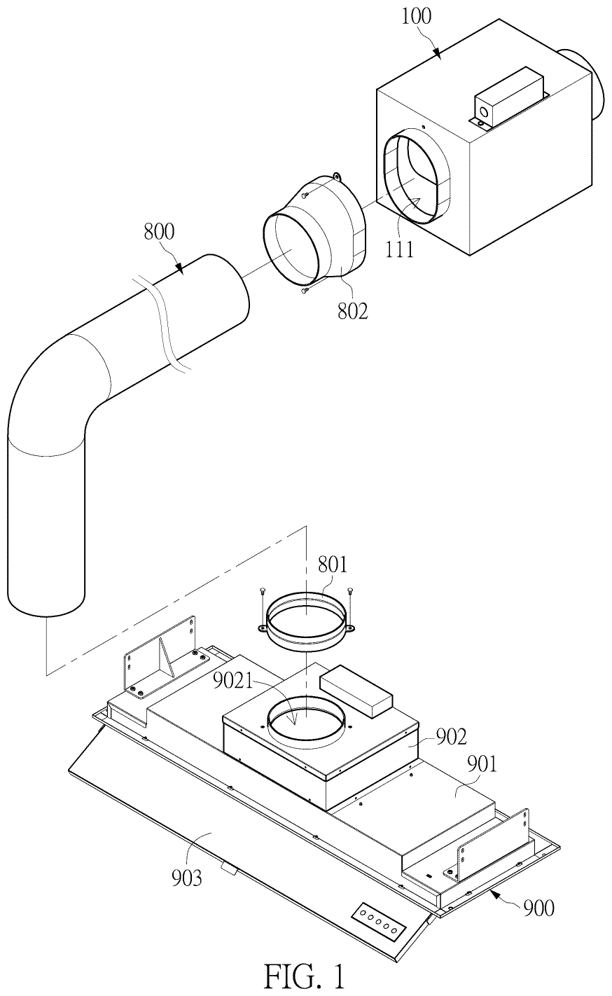

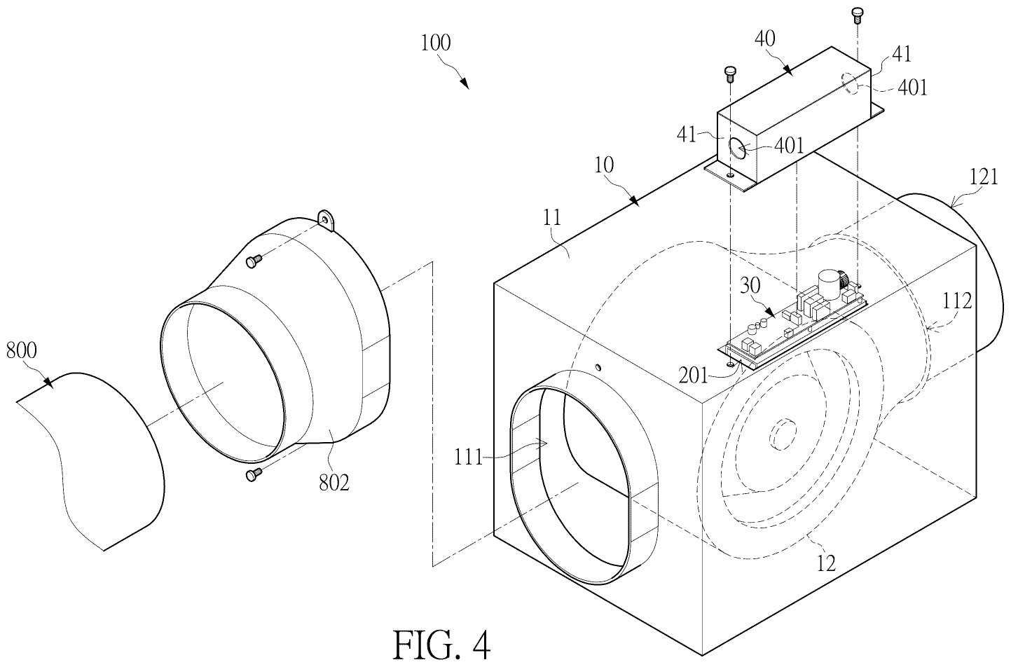

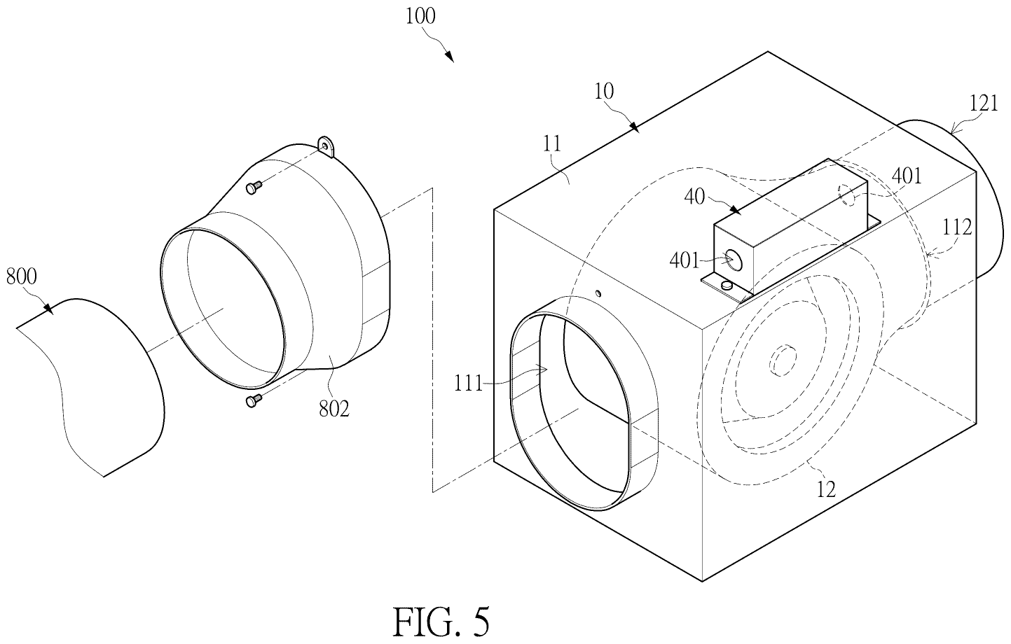

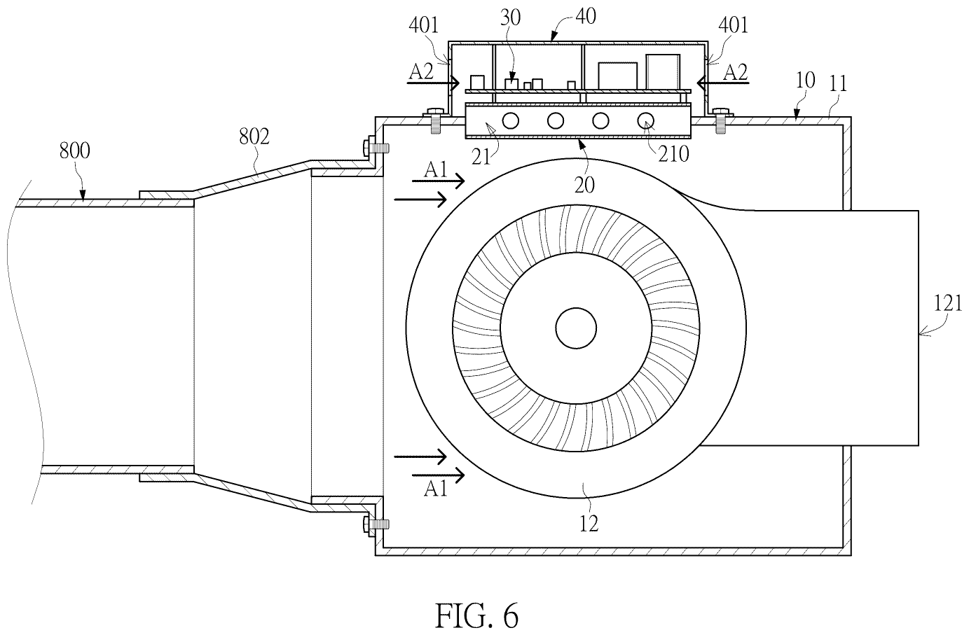

Referring to FIG. 1 to FIG. 6, the present disclosure provides a split-type range hood having a relay fan for cooling a circuit board (hereunder referred to as a split-type range hood for short). The split-type range hood includes a range hood body 900, an air duct 800, and a relay fan 100. The relay fan 100 is disposed outside of the range hood body 900, and the range hood body 900 is connected to the relay fan 100 via the air duct 800, so as to discharge airborne grease.

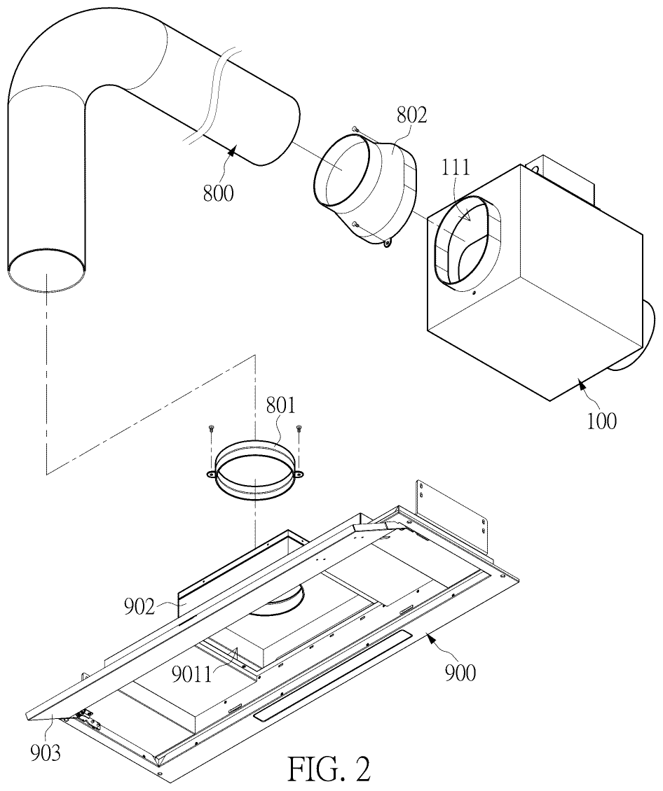

As shown in FIG. 1 and FIG. 2, the range hood body 900 includes a chassis 901 and a smoke collecting box 902. In the present embodiment, the chassis 901 is substantially a rectangular housing, and has an intake opening 9011. The intake opening 9011 is an inlet of the airborne grease, and a grease filter or a splitter can be disposed according to practical requirements. The shape of the intake opening 9011 is square in the present embodiment, but is not limited thereto. The smoke collecting box 902 is disposed on the chassis 901, and covers the intake opening 9011. The smoke collecting box 902 has an exhaust opening 9021, and the exhaust opening 9021 of the smoke collecting box 902 is in air communication with the intake opening 9011 of the chassis 901.

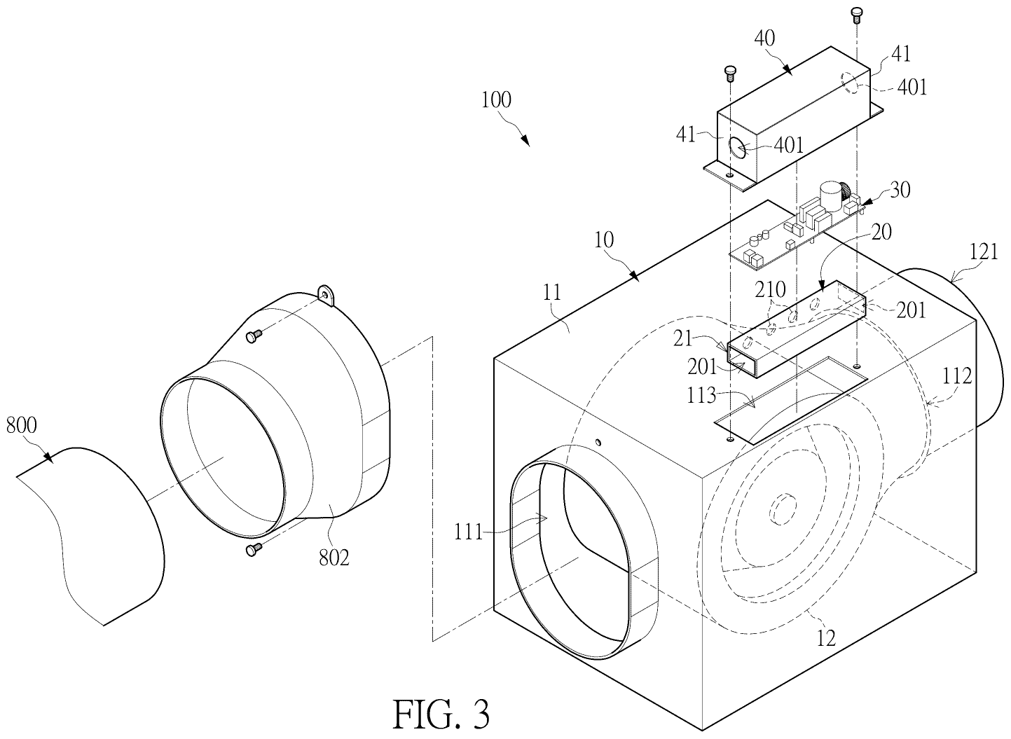

In order to extend a smoke collecting area for collection of the airborne grease, the range hood body 900 of the present embodiment further includes a smoke deflector 903, and an inclined angle of the smoke deflector 903 is adjustable. The smoke deflector 903 is rotatably connected to one side of a bottom portion of the chassis 901. When in use, the smoke deflector 903 is rotatable in a direction away from the intake opening 9011, so as to extend the smoke collecting area. When not in use, the smoke deflector 903 can also be rotated in a direction toward the intake opening 9011, so as to shield the bottom portion of the chassis 901 and the intake opening 9011 for aesthetic purposes. As shown in FIG. 3 to FIG. 6, the relay fan 100 essentially includes a suction motor 10, a heat-dissipation base 20, and a circuit board 30. The suction motor 10 includes an outer housing 11 and a motor body 12. The outer housing 11 can be a metal hollow body. The outer housing 11 has a first opening 111 and a second opening 112, and the first opening 111 and the second opening 112 are respectively formed on two opposite sides of the outer housing 11. The motor body 12 is disposed in the outer housing 11. An outlet 121 is formed at one end of the motor body 12, and the outlet 121 corresponds in position to the second opening 112. The outlet 121 of the motor body 12 can also extend out of the outer housing 11 through the second opening 112, so that the airborne grease suctioned by the suction motor 10 can be outwardly discharged.

One end of the air duct 800 is in air communication with the exhaust opening 9021 of the smoke collecting box 902 (as shown in FIG. 1), and another end of the air duct 800 is in air communication with the first opening 111 of the outer housing 11 (as shown in FIG. 3). The one end of the air duct 800 can be connected to the exhaust opening 9021 of the smoke collecting box 902 via a first sleeve 801, and the another end of the air duct 800 can be connected to the first opening 111 of the outer housing 11 via a second sleeve 802. Since the first sleeve 801 and the second sleeve 802 are commercially available products, and the structure of a sleeve is not limited in the present disclosure, details thereof will not be reiterated herein.

The circuit board 30 is electrically connected to the motor body 12 of the suction motor 10, so as to provide electricity and control activation/deactivation or a rotational speed of the motor body 12 of the suction motor 10. In addition, a high-power electronic component (e.g., a power transistor) is disposed on the circuit board 30. The power transistor can be a single power device (such as a metal-oxide-semiconductor field-effect transistor (MOSFET) or an insulated-gate bipolar transistor (IGBT)), but can also be a power module. The circuit board 30 is disposed on the heat-dissipation base 20, and the heat-dissipation base 20 can be directly disposed on the outer housing 11 of the suction motor 10 to form thermal contact conductance with the outer housing 11. As such, the heat-dissipation base 20 can be cooled by a suction airflow A1 formed in the outer housing 11 during operation of the suction motor 10. In the present embodiment, a third opening 113 can be further formed on the outer housing 11, and corresponds in shape or size to the heat-dissipation base 20. Through the third opening 13, the heat-dissipation base 20 can sink into the outer housing 11 in a complete or partial manner. When the circuit board 30 becomes hot as a result of a high rotational speed and high power consumption of the suction motor 10, the heat-dissipation base 20 can be cooled due to an increase of the suction airflow A1 in the outer housing 11, thereby effectively cooling the circuit board 30.

An outer cover shell 40 is further provided in the present embodiment, so as to better assist in cooling the circuit board 30. The outer cover shell 40 covers an outer periphery of the circuit board 30. One or more drain holes 401 are formed on the outer cover shell 40. When the circuit board 30 becomes hot as a result of the high rotational speed and the high power consumption of the suction motor 10, apart from cooling the heat-dissipation base 20 with the increase of the suction airflow A1 in the outer housing 11, the circuit board 30 can also be more effectively cooled by driving an external airflow A2 to pass through the drain hole 401 of the outer cover shell 40, the circuit board 30, and the heat-dissipation base 20.

Specifically, the heat-dissipation base 20 can be a metal heat-dissipation base that is plate-shaped or an aluminum extrusion heat-dissipation base. Preferably, the heat-dissipation base 20 is a metal heat-dissipation base that has a hollow rectangular column shape, and has two side walls and two side openings 201. One of the side walls is a heat-dissipation wall 21, and the two side openings 201 are respectively formed on two sides of the heat-dissipation wall 21. A plurality of heat-dissipation holes 210 are further formed on the heat-dissipation wall 21, and are in air communication with the two side openings 201. The two side openings 201 are in air communication with an inner space of the outer cover shell 40 and the one or more drain holes 401, so that the external airflow A2 can flow from the drain hole 401 to the heat-dissipation base 20 through the side opening 201, and can flow into an inner space of the outer housing 11 through the heat-dissipation holes 210. Furthermore, due to the heat-dissipation base 20 partially sinking into the outer housing 11, the suction airflow A1 formed in the outer housing 11 during operation of the suction motor 10 can also flow to the heat-dissipation base 20 through the side openings 201. Since the external airflow A2 and the suction airflow A1 simultaneously flow to and cool the heat-dissipation base 20, the circuit board 30 can be more effectively cooled.

More specifically, the outer cover shell 40 can be made of a metal plate or a plastic plate. The outer cover shell 40 has a hollow box shape, and includes two side cover plates 41 that are opposite to each other. One drain hole 401 is formed on each side cover plate 41, so that the external airflow A2 can be introduced through the two opposite drain holes 401 of the outer cover shell 40. In addition, an outer periphery of the outer cover shell 40 is completely and tightly joined to an edge of the third opening 113. That is to say, dimensions (a length and a width) of the outer cover shell 40 are greater than or equal to dimensions (a length and a width) of the third opening 113.

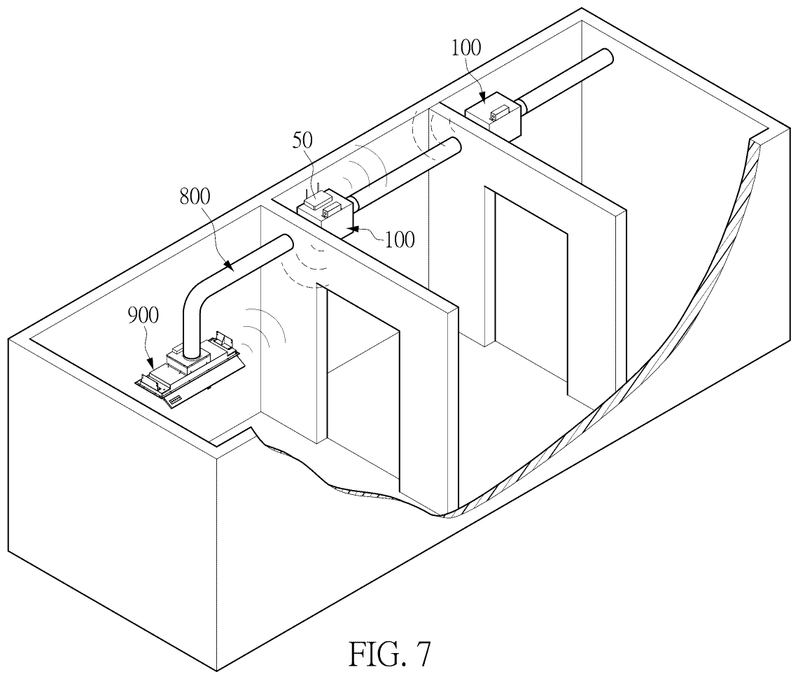

Referring to FIG. 7, the relay fan 100 of the present embodiment is preferably interlinked with the range hood body 900 in a wireless manner. That is, when the range hood body 900 is activated, a relay fan activation signal is wirelessly transmitted to the circuit board 30 of the relay fan 100, and the suction motor 10 of the relay fan 100 is driven to be synchronously activated. However, with the popularization of an island-type kitchen or an open kitchen, the kitchen is gradually in closer proximity to the center of a household, and a length of the air duct 800 for reaching a balcony or outdoors becomes longer, thereby negatively affecting exhaust efficiency. Therefore, more than one (two, three, or even more) relay fan 100 is needed. When the range hood body 900 is activated, the wirelessly-transmitted relay fan activation signal can often be reduced due to obstruction of a steel frame of a building and multiple wall bodies, and is usually only transmitted to the relay fan 100 that is closest in distance. Due to not receiving said activation signal, other relay fans 100 that are further in distance often cannot be synchronously activated. As such, in the present embodiment, the relay fan 100 that is closest in distance further includes a relay transceiver 50. The relay transceiver 50 is electrically connected to the circuit board 30, and can be disposed at an appropriate location of the outer housing 11 or can be integrated with the circuit board 30. In this way, after the relay transceiver 50 receives the relay fan activation signal transmitted by the activated range hood body 900, the relay fan activation signal is amplified and broadcasted. Since an amplified signal can be broadcasted to a greater distance, the other relay fans 100 that are further in distance can wirelessly receive the relay fan activation signal and be activated in a synchronous manner. Alternatively, the relay fan activation signal can be broadcasted by the relay transceivers 50 of the relay fans 100 that are serially connected in a one-by-one manner, so as to reach a greater distance.

### Beneficial Effects of the Embodiment

In conclusion, the split-type range hood having the relay fan for cooling the circuit board provided by the present disclosure includes the range hood body 900, the air duct 800, and the relay fan 100. The range hood body 900 includes the chassis 901 and the smoke collecting box 902. The chassis 901 has the intake opening 9011. The smoke collecting box 902 is disposed on the chassis 901, and covers the intake opening 9011. The smoke collecting box 902 has the exhaust opening 9021, and the exhaust opening 9021 of the smoke collecting box 902 is in air communication with the intake opening 9011 of the chassis 901. The relay fan 100 is disposed outside of the range hood body 900. The relay fan 100 includes the suction motor 10, the heat-dissipation base 20, and the circuit board 30. The suction motor 10 includes the outer housing 11 and the motor body 12. The outer housing 11 has the first opening 111 and the second opening 112 that are opposite to each other. The one end of the air duct 800 is in air communication with the exhaust opening 9021, and the another end of the air duct 800 is in air communication with the first opening 111. The motor body 12 is disposed in the outer housing 11. The outlet 121 that corresponds in position to the second opening 112 is formed at the one end of the motor body 12. The heat-dissipation base 20 is disposed on the outer housing 11 of the suction motor 10. The circuit board 30 is electrically connected to the suction motor 10, and is disposed on the heat-dissipation base 20, so that the circuit board 30 is cooled by cooling the heat-dissipation base 20 with the suction airflow A1 of the suction motor 10 during operation. Accordingly, use convenience and safety can be significantly improved, thereby solving an issue that has long troubled manufacturers and users.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A split-type range hood, comprising:
a range hood body, wherein the range hood body includes a chassis and a smoke collecting box, the chassis has an intake opening, the smoke collecting box is disposed on the chassis, the smoke collecting box covers the intake opening, the smoke collecting box has an exhaust opening, and the exhaust opening of the smoke collecting box is in air communication with the intake opening of the chassis;
an air duct; and
a relay fan, wherein the relay fan is disposed outside of the range hood body, and includes:
a suction motor, wherein the suction motor includes an outer housing and a motor body, and the outer housing has a first opening and a second opening that are opposite to each other; wherein one end of the air duct is in air communication with the exhaust opening, and another end of the air duct is in air communication with the first opening; wherein the motor body is disposed in the outer housing, and an outlet that corresponds in position to the second opening is formed at one end of the motor body;
a heat-dissipation base disposed on the outer housing of the suction motor; and
a circuit board, wherein the circuit board is electrically connected to the motor body of the suction motor, and is disposed on the heat-dissipation base, so that the circuit board is cooled by cooling the heat-dissipation base with a suction airflow of the suction motor during operation.

2. The split-type range hood according to claim 1, wherein the range hood body further includes a smoke deflector, an inclined angle of the smoke deflector is adjustable, and the smoke deflector is rotatably connected to one side of a bottom portion of the chassis.

3. The split-type range hood according to claim 1, wherein a third opening that corresponds in position to the heat-dissipation base is formed on the outer housing of the suction motor, and the heat-dissipation base sinks into the outer housing through the third opening.

4. The split-type range hood according to claim 3, wherein the relay fan further includes an outer cover shell, the outer cover shell covers an outer periphery of the circuit board, and one or more drain holes are formed on the outer cover shell.

5. The split-type range hood according to claim 4, wherein the heat-dissipation base is a metal heat-dissipation base that has a hollow rectangular column shape, the heat-dissipation base partially sinks into the outer housing, the heat-dissipation base has a heat-dissipation wall and two side openings, and the two side openings are respectively formed on two sides of the heat-dissipation wall; wherein a plurality of heat-dissipation holes are formed on the heat-dissipation wall, and are in air communication with the two side openings; wherein the two side openings are in air communication with an inner space of the outer cover shell and the one or more drain holes.

6. The split-type range hood according to claim 5, wherein the outer cover shell includes two side cover plates that are opposite to each other, and one of the drain holes is formed on each of the two side cover plates.

7. The split-type range hood according to claim 1, wherein the one end of the air duct is connected to the exhaust opening of the smoke collecting box via a first sleeve, and the another end of the air duct is connected to the first opening of the outer housing via a second sleeve.

8. The split-type range hood according to claim 1, wherein the relay fan further includes a relay transceiver; wherein the relay transceiver is electrically connected to the circuit board, and is configured to amplify and broadcast a relay fan activation signal transmitted by the range hood body during activation.
